(19) United States
(12) Patent Application Publication
(10) Pub. No.: US 2026/0334060 A1
(43) Pub. Date: Oct. 22, 2026

(54) DISPLAY PANEL AND DISPLAY DEVICE

(71) Applicants: TCL China Star Optoelectronics Technology Co., Ltd., Shenzhen (CN); Wuhan China Star Optoelectronics Semiconductor Display Technology Co., Ltd., Wuhan (CN)

(72) Inventors: Xiaolin YAN, Shenzhen (CN); Bin FU, Shenzhen (CN); Xiaowei NIE, Shenzhen (CN)

(73) Assignees: TCL China Star Optoelectronics Technology Co., Ltd., Shenzhen (CN); Wuhan China Star Optoelectronics Semiconductor Display Technology Co., Ltd., Wuhan (CN)

(21) Appl. No.: 19/704,420

(22) Filed: Jun. 11, 2026

(30) Foreign Application Priority Data
Dec. 16, 2025 (CN) 202511893073.2

(51) Int. Cl. H10K 59/80; H10K 59/00; H10K 59/122

(52) U.S. Cl. CPC H10K 59/873; H10K 59/122; H10K 59/771

(57) ABSTRACT

The present disclosure provides a display panel and a display device. The display panel includes a first retaining wall and at least one light-emitting common layer. The first retaining wall is located in a non-display area and extends along an edge of a display area. The light-emitting common layer is partially disposed on the first retaining wall. The first retaining wall includes a padding portion and a partition portion stacked on the padding portion. At least one lateral surface of the padding portion of the first retaining wall contracts inwardly relative to at least one lateral surface of the partition portion on the same side to form a first undercut opening, so that the light-emitting common layer is interrupted at the first undercut opening.

### RELATED APPLICATION

This application claims the benefit of priority of Chinese Patent Application No. 202511893073.2 filed on Dec. 16, 2025. The contents of the above applications are all incorporated by reference as if fully set forth herein in their entirety.

### TECHNICAL FIELD

The present disclosure relates to the field of display technologies, and in particular, to a display panel and a display device.

### BACKGROUND

With the development of display technology, in order to ensure the front photographing effect of mobile phones, an opening is usually formed in the display panel. The encapsulation reliability of the opening area is affected by the side exposure of an organic evaporation coating layer, and the penetration of moisture and oxygen at high temperature affects the reliability of a display screen.

In order to improve the influence of water vapor permeation, several metal partition structures are usually placed between the opening area and a display area, and the organic material and a cathode are interrupted by the metal partition structures. Due to incomplete interrupting of the cathode at some positions, continuous overlap exists between the cathode and the metal partition structure, which is prone to electrochemical corrosion and deteriorates the influence of water vapor permeation, resulting in poor display of the display panel.

Therefore, it is necessary to provide a display panel and a display device to improve this defect.

### SUMMARY

According to a first aspect of the present disclosure, a display panel is provided. The display panel includes a display area and a non-display area, and the display panel includes:
a first retaining wall located in the non-display area and extending along an edge of the display area; and
at least one light-emitting common layer partially disposed on the first retaining wall.

The first retaining wall includes a padding portion and a partition portion stacked on the padding portion, at least one lateral surface of the padding portion contracts inwardly relative to at least one lateral surface of the partition portion on a same side to form a first undercut opening, and the light-emitting common layer is interrupted at the first undercut opening.

According to a second aspect of the present disclosure, a display device is provided, and the display device includes the display panel as described above.

Other features and advantages of the present disclosure will be described in detail in the following detailed description.

### BRIEF DESCRIPTION OF DRAWINGS

To describe the technical solutions in the embodiments of the present disclosure more clearly, the following provides a brief introduction to the accompanying drawings that are required for the description of the embodiments. Apparently, the accompanying drawings in the following description illustrate merely some embodiments of the present disclosure, and those skilled in the art may further obtain other drawings based on these accompanying drawings without creative efforts.

For a more complete understanding of the present disclosure and its beneficial effects, the following description is made with reference to the accompanying drawings, in which the same reference numerals represent the same parts in the following description.

FIG. 1 is a top view of a display panel provided in embodiments of the present disclosure.

FIG. 2 is a cross-sectional view of a display panel provided in embodiments of the present disclosure along an A-A′ direction shown in FIG. 1.

FIG. 3 is a schematic structural diagram of a first retaining wall in a display panel provided in embodiments of the present disclosure.

FIG. 4 is a schematic diagram of a film layer structure of a part of a display panel located in a display area provided in embodiments of the present disclosure.

FIG. 5 is a schematic structural diagram of another first retaining wall in a display panel provided in embodiments of the present disclosure.

FIG. 6 is a cross-sectional view of another display panel provided in embodiments of the present disclosure along the A-A′ direction shown in FIG. 1.

FIG. 7 is a schematic structural diagram of a first retaining wall in another display panel provided in embodiments of the present disclosure.

FIG. 8a to FIG. 8c are schematic flowcharts of a method for manufacturing a display panel provided in embodiments of the present disclosure.

FIG. 9 is a schematic structural diagram of a display device provided in embodiments of the present disclosure.

### DETAILED DESCRIPTION

The following clearly and completely describes the technical solutions in the embodiments of the present disclosure with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts shall fall within the protection scope of the present disclosure.

Embodiments of the present disclosure provide a display panel and a display device, which can solve the problem of poor display.

In order to achieve the above objective, according to a first aspect of the present disclosure, a display panel is provided. The display panel includes a display area and a non-display area, and the display panel includes:
a first retaining wall located in the non-display area and extending along an edge of the display area; and
at least one light-emitting common layer partially disposed on the first retaining wall.

The first retaining wall includes a padding portion and a partition portion stacked on the padding portion, at least one lateral surface of the padding portion contracts inwardly relative to at least one lateral surface of the partition portion on a same side to form a first undercut opening, and the light-emitting common layer is interrupted at the first undercut opening.

In some embodiments, a distance by which a bottom of the at least one lateral surface of the padding portion contracts inwardly relative to a bottom of the at least one lateral surface of the partition portion on the same side is greater than a thickness of the light-emitting common layer.

In some embodiments, the partition portion and the light-emitting common layer adjacent to the partition portion are spaced apart and insulated from each other.

In some embodiments, a thickness of the padding portion is greater than a thickness of the light-emitting common layer.

In some embodiments, the display panel includes an organic material layer, and the padding portion and the organic material layer are disposed in a same layer and made of a same material.

In some embodiments, a thickness of the padding portion is less than a thickness of a part of the organic material layer located in the display area.

In some embodiments, a ratio of the thickness of the padding portion to the thickness of the part of the organic material layer located in the display area is greater than or equal to 3:25 and is less than or equal to 2:3.

In some embodiments, the display panel includes at least one source and drain layer, and the at least one source and drain layer is disposed on the organic material layer.

In some embodiments, an included angle between a reference plane and a tangent line of any point on the at least one lateral surface of the padding portion is greater than or equal to 50 degrees and is less than or equal to 80 degrees, and the reference plane is parallel to a light-emitting surface of the display panel.

In some embodiments, the first retaining wall further includes a blocking portion, the blocking portion is stacked on the partition portion, and a thickness of the blocking portion is greater than a thickness of the padding portion and a thickness of the partition portion.

In some embodiments, one lateral surface of the partition portion is provided with the first undercut opening, and a part of the blocking portion is disposed on the padding portion and covers another lateral surface of the partition portion.

In some embodiments, the display panel includes two first retaining walls, the two first retaining walls include a first sub-retaining wall and a second sub-retaining wall adjacent to and spaced apart from each other, and the second sub-retaining wall is located on a side of the first sub-retaining wall away from the display area.

In some embodiments, a lateral surface of the padding portion of the first sub-retaining wall close to the second sub-retaining wall is provided with the first undercut opening, and a lateral surface of the padding portion of the second sub-retaining wall close to the first sub-retaining wall is provided with the first undercut opening.

In some embodiments, the display panel includes a plurality of partition members, the light-emitting common layer is interrupted at the partition members, at least one of the partition members is disposed on a side of the first sub-retaining wall close to the display area, and the plurality of partition members are disposed on a side of the second sub-retaining wall away from the display area; and
in a direction parallel to a light-emitting surface of the display panel, a distance between the partition portion of the first sub-retaining wall and the partition portion of the second sub-retaining wall is equal to a distance between two adjacent ones of the partition members.

In some embodiments, the display panel includes a substrate and a second retaining wall, the first retaining wall and the second retaining wall are disposed on the substrate, and the second retaining wall is located on a side of the first retaining wall away from the display area; and
a vertical distance between a top of the first retaining wall and the substrate is greater than a vertical distance between a top of the second retaining wall and the substrate.

In some embodiments, the at least one lateral surface of the partition portion is provided with a second undercut opening, and the light-emitting common layer is interrupted at the second undercut opening.

In some embodiments, a distance by which a bottom of the at least one lateral surface of the padding portion contracts inwardly relative to a bottom of the at least one lateral surface of the partition portion on the same side is greater than a depth of the second undercut opening.

In some embodiments, the partition portion includes a first partition sub-portion, a second partition sub-portion, and a third partition sub-portion stacked in sequence; and
at least one lateral surface of the second partition sub-portion contracts inwardly relative to at least one lateral surface of the first partition sub-portion and at least one lateral surface of the third partition sub-portion on a same side to form the second undercut opening.

In some embodiments, the display panel includes a plurality of light-emitting common layers, and the plurality of light-emitting common layers include an organic common layer and a cathode layer disposed on the organic common layer.

According to a second aspect of the present disclosure, a display device is provided, and the display device includes the display panel as described above.

In the display panel of the embodiments of the present disclosure, at least one lateral surface of the padding portion of the first retaining wall contracts inwardly relative to at least one lateral surface of the partition portion on the same side to form the first undercut opening, so that the light-emitting common layer is interrupted at the first undercut opening, thereby preventing electrochemical corrosion of the light-emitting common layer in the non-display area, improving the encapsulation performance of the display panel, avoiding poor display, and improving the reliability of the display panel.

Embodiments of the present disclosure provide a display panel. The display panel includes a display area and a non-display area. The display panel includes a first retaining wall and at least one light-emitting common layer. The first retaining wall is located in the non-display area and extends along an edge of the display area. The light-emitting common layer is partially disposed on the first retaining wall. The first retaining wall includes a padding portion and a partition portion stacked on the padding portion. At least one lateral surface of the padding portion contracts inwardly relative to at least one lateral surface of the partition portion on the same side to form a first undercut opening, and the light-emitting common layer is interrupted at the first undercut opening.

In the embodiments of the present disclosure, at least one lateral surface of the padding portion of the first retaining wall contracts inwardly relative to at least one lateral surface of the partition portion on the same side to form the first undercut opening, so that the light-emitting common layer can be prevented from continuously forming a film on the lateral surface of the first retaining wall, so as to ensure that the light-emitting common layer is interrupted at the first undercut opening. In this way, the light-emitting common layer in the non-display area is prevented from electrochemical corrosion, thereby improving the encapsulation performance of the display panel, avoiding poor display, and improving the reliability of the display panel.

As shown in FIG. 1, FIG. 1 is a top view of the display panel provided in embodiments of the present disclosure. The display panel 100 includes a display area AA and a non-display area NA, the display area AA is an area for displaying images, and the non-display area NA is an area for placing peripheral circuits or for transmitting light.

In some embodiments, as shown in FIG. 1, the non-display area NA includes a first non-display area NA1 and a second non-display area NA2, the display area AA is disposed at a periphery of the first non-display area NA1, and the second non-display area NA is disposed at a periphery of the display area AA.

In some embodiments, the first non-display area NA1 is a region for transmitting light, the display panel 100 is provided with a light-transmitting hole H located in the first non-display area NA1, and the light-transmitting hole H may at least partially penetrate the display panel 100 in a thickness direction of the display panel to provide a path for light to pass through the display panel.

In some embodiments, the second non-display area NA2 is a region for placing peripheral circuits and peripheral traces. For example, the display panel includes peripheral circuits and peripheral traces, the peripheral circuits and the peripheral traces may be disposed in the second non-display area NA2, and the peripheral circuits may include, but is not limited to, a gate driving circuit, an electrostatic protection circuit, a multiplexing circuit, etc.

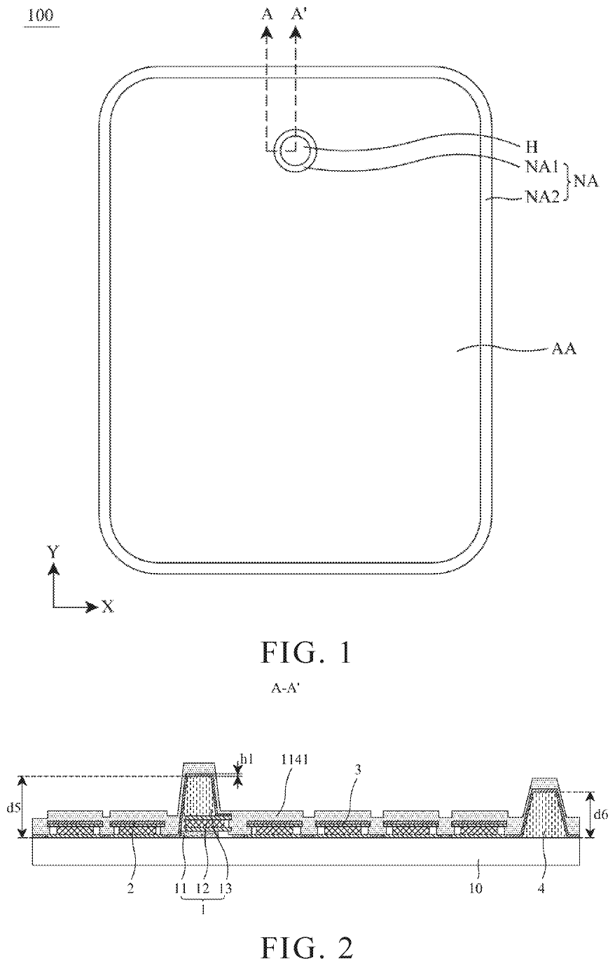

With reference to FIG. 1 and FIG. 2, FIG. 2 is a cross-sectional view of the display panel provided in embodiments of the present disclosure along an A-A′ direction shown in FIG. 1, the display panel 100 includes a first retaining wall 1 and at least one light-emitting common layer 2. The first retaining wall 1 is located in the first non-display area NA1 and extends along an edge of the display area AA, and the light-emitting common layer 2 is partially disposed on the first retaining wall 1.

In some embodiments, the first non-display area NA1 may include an opening sub-region and a transition sub-region (not shown in the figures), and the transition sub-region is located between the opening sub-region and the display area AA. Te first retaining wall 1 is disposed in the transition sub-region to separate the light-emitting common layer in the display area from the light-emitting common layer in the transition sub-region.

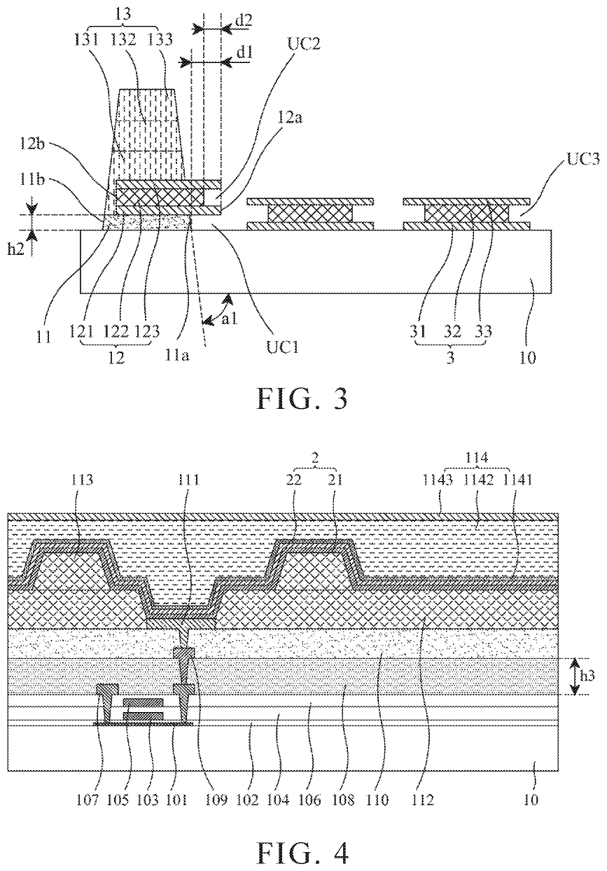

As shown in FIG. 2 and FIG. 3, FIG. 3 is a schematic structural diagram of the first retaining wall of the display panel provided in embodiments of the present disclosure. The first retaining wall 1 includes a padding portion 11 and a partition portion 12 stacked on the padding portion 11. At least one lateral surface of the padding portion 11 contracts inwardly relative to at least one lateral surface of the partition portion 12 on the same side to form a first undercut opening UC1, and the light-emitting common layer 2 is interrupted at the first undercut opening UC.

In the embodiments, the first retaining wall 1 is disposed in the first non-display area NA1, the first non-display area NA1 is provided with the light-transmitting hole H, and the light-transmitting hole H penetrates the display panel 100 in the thickness direction. By contracting at least one lateral surface of the padding portion 11 of the first retaining wall 1 inwardly relative to at least one lateral surface of the partition portion 12 on the same side to form the first undercut opening UC1, the light-emitting common layer 2 can be prevented from forming a film on the lateral surface of the padding portion 11, so that the light-emitting common layer 2 is interrupted at the padding portion 11, and the connection between the light-emitting common layer 2 in the display area AA and the light-emitting common layer 2 in the non-display area NA is cut off, which can not only prevent electrochemical corrosion between the light-emitting common layer 2 in the non-display area NA and an overlapped metal film layer, but also cut off the path of water vapor penetrating from the light-transmitting hole H to the display area AA through the light-emitting common layer 2, thereby improving the encapsulation performance of the display panel, avoiding poor display, and improving the reliability of the display panel.

In some embodiments, as shown in FIG. 2 and FIG. 3, the padding portion 11 includes a first lateral surface 11a and a second lateral surface 11b, the first lateral surface 11a is a lateral surface of the padding portion 11 away from the display area AA, and the second lateral surface 11b is a lateral surface of the padding portion 11 close to the display area AA. The partition portion 12 includes a third lateral surface 12a and a fourth lateral surface 12b, the third lateral surface 12a is a lateral surface of the partition portion 12 away from the display area AA, and the fourth lateral surface 12b is a lateral surface of the partition portion 12 close to the display area AA.

The first lateral surface 11a and the third lateral surface 12a are located on the same side of the first retaining wall 1, the first lateral surface 11a and the third lateral surface 12a are not coplanar, and the first lateral surface 11a contracts inwardly relative to the third lateral surface 12a. An edge of the partition portion 12 away from the display area AA exceeds an edge of the padding portion 11 away from the display area AA, and the padding portion 11 and a part of the partition portion 12 beyond the padding portion 11 define the first undercut opening UC1. The part of the partition portion 12 beyond the padding portion 11 shields the first lateral surface 11a of the padding portion 11, which can prevent a material of the light-emitting common layer 2 from being deposited on the first lateral surface 11a to form a film, so that the light-emitting common layer 2 is interrupted at the first undercut opening UC1.

As shown in FIG. 2 and FIG. 3, a middle part of the third lateral surface 12a of the partition portion 12 in the thickness direction of the display panel contracts inwardly relative to upper and lower portions to define a second undercut opening UC2. The second undercut opening UC2 can prevent the light-emitting common layer 2 from continuously forming a film on the third lateral surface 12a of the partition portion 12, so that the light-emitting common layer 2 is interrupted at the second undercut opening UC2.

In the embodiments, the second undercut opening UC2 and the first undercut opening UC1 are formed on the same lateral surface of the first retaining wall 1, and are arranged at intervals in the thickness direction of the display panel. A composite undercut opening structure formed by the first undercut opening UC1 and the second undercut opening UC2 can further ensure that the light-emitting common layer 2 is interrupted at the first undercut opening UC1 and the second undercut opening UC2, so as to improve the encapsulation performance of the display panel and avoid poor display, thereby improving the reliability of the display panel.

In some embodiments, a distance by which a bottom of the at least one lateral surface of the padding portion 11 contracts inwardly relative to a bottom of the at least one lateral surface of the partition portion 12 on the same side is greater than the thickness of the light-emitting common layer 2.

As shown in FIG. 2 and FIG. 3, the distance by which the bottom of the first lateral surface 11a of the padding portion 11 contracts inwardly relative to the bottom of the third lateral surface 12a of the partition portion 12 on the same side is defined as a first distance d1, the thickness of the part of the light-emitting common layer 2 located on the first retaining wall 1 is defined as a first thickness h1, and the first distance d1 is greater than the first thickness h1, so that the light-emitting common layer 2 can be prevented from filling a space by which the first lateral surface 11a of the padding portion 11 contracts inwardly relative to the third lateral surface 12a of the partition portion 12 to continuously form a film on the first lateral surface 11a and the third lateral surface 12a, thereby ensuring that the light-emitting common layer 2 is interrupted at the first lateral surface 11a of the padding portion 11.

In some embodiments, the padding portion 11 is spaced apart from and insulated from the adjacent light-emitting common layer 2.

As described in conjunction with FIG. 2 and FIG. 3, a part of the light-emitting common layer 2 is formed on the first retaining wall 1, and a part of the light-emitting common layer 2 is formed on the substrate 10 on a side of the first retaining wall 1 away from the display area AA. A thickness of the part of the light-emitting common layer 2 located on the first retaining wall 1 is greater than or equal to a thickness of the part of the light-emitting common layer 2 located on the substrate 10. The part of the light-emitting common layer 2 located on the first retaining wall 1 and the part of the light-emitting common layer 2 located on the substrate 10 are separated by the first undercut opening UC1 and the second undercut opening UC2. The padding portion 11 and the light-emitting common layer 2 located on the substrate 10 adjacent to the right side of the padding portion 11 are spaced apart and insulated from each other, so as to cut off the connection between the cathode in the non-display area NA and the cathode in the display area AA, and prevent the light-emitting common layer in the non-display area from being electrochemically corroded, thereby improving the encapsulation performance of the display panel, avoiding poor display, and improving the reliability of the display panel.

In some embodiments, the thickness of the padding portion 11 is greater than the thickness of the light-emitting common layer 2.

As shown in FIG. 2 and FIG. 3, the padding portion 11 and the light-emitting common layer 2 on the adjacent side are formed on the same plane, and since the thickness of the padding portion 11 is greater than the thickness of the light-emitting common layer 2, a height of the bottom of the partition portion 12 is greater than the thickness of the light-emitting common layer 2, so as to prevent the light-emitting common layer 2 from overlapping with the partition portion 12, thereby ensuring that the padding portion 11 and the adjacent light-emitting common layer 2 are spaced apart and insulated from each other.

In some embodiments, the distance by which the bottom of the at least one lateral surface of the padding portion 11 contracts inwardly relative to the bottom of the at least one lateral surface of the partition portion 12 on the same side is greater than a depth d2 of the second undercut opening UC2.

As shown in FIG. 3, the partition portion 12 includes a first partition sub-portion 121, a second partition sub-portion 122, and a third partition sub-portion 123 stacked in sequence. At least one lateral surface of the second partition sub-portion 122 contracts inwardly relative to at least one lateral surface of the first partition sub-portion 121 and at least one lateral surface of the third partition sub-portion 123 on the same side to form the second undercut opening UC2. A depth of the second undercut opening UC2 refers to a distance between a bottom of the lateral surface of the second partition sub-portion 122 and a bottom of the lateral surface of the first partition sub-portion 121. The second undercut opening UC2 has a first depth d2, and the first distance d1 is greater than the first depth d2, that is, the lateral surface of the first lateral surface 11a of the padding portion 11 contracts inwardly relative to the lateral surface of the second partition sub-portion 122 on the same side, so that the light-emitting common layer 2 can be prevented from filling the space where the first lateral surface 11a of the padding portion 11 contracts inwardly relative to the third lateral surface 12a of the partition portion 12 to form a continuous film on the first lateral surface 11a and the third lateral surface 12a, thereby ensuring that the light-emitting common layer 2 is interrupted at the first lateral surface 11a of the padding portion 11.

In some embodiments, the first distance d1 by which the bottom of the first lateral surface 11a of the padding portion 11 contracts inwardly relative to the bottom of the third lateral surface 12 a of the partition portion 12 on the same side is greater than 0.3 microns and is less than or equal to 1 microns. For example, the first distance d1 may be 0.32 microns, 0.35 microns, 0.4 microns, 0.5 microns, 0.7 microns, 0.9 microns, or 1 micron, etc.

In some embodiments, the first depth d2 of the second undercut opening UC2 is greater than or equal to 0.2 microns and is less than or equal to 0.4 microns. For example, the first depth d2 may be 0.2 microns, 0.25 microns, 0.3 microns, 0.35 microns, or 0.4 microns, etc.

In some embodiments, the display panel includes an organic material layer, and the padding portion 11 and the organic material layer are disposed in the same layer and made of the same material.

In the actual manufacturing process, the padding portion 11 and the organic material layer 108 may be manufactured simultaneously by the same process, and the padding portion 11 may also be regarded as a part of the organic material layer 108. The padding portion 11 is manufactured by the process of the organic material layer 108, which can ensure that the light-emitting common layer 2 is interrupted at the first undercut opening UC1 and the second undercut opening UC2 without increasing the film layer structure and the process of the display panel, thereby improving the encapsulation performance of the display panel, avoiding poor display, and improving the reliability of the display panel.

In some embodiments, the display panel includes at least one source and drain layer, and the source and drain layer is disposed on the organic material layer.

In some embodiments, with reference to FIG. 4, FIG. 4 is a schematic diagram of a film layer structure of a part of the display panel located in the display area provided in embodiments of the present disclosure. The display panel includes a substrate 10, an active layer 101, a first gate insulating layer 102, a first gate layer 103, a second gate insulating layer 104, a second gate layer 105, an interlayer dielectric layer 106, a first source and drain layer 107, an organic material layer 108, a second source and drain layer 109, a planarization layer 110, an anode layer 111, a pixel definition layer 112, a supporting layer 113, a light-emitting common layer 2, and an encapsulation layer 114 that are sequentially stacked. The organic material layer 108 is disposed on the first source and drain layer 107 and the interlayer dielectric layer 106, and the second source and drain layer 109 is disposed on the organic material layer 108.

The material of the organic material layer 108 includes an organic material, the organic material has fluidity, which can improve the flatness of the organic material layer 108, so as to facilitate the subsequent preparation of the source and drain layer and the light-emitting layer. The organic material layer 108 can also be regarded as a first planarization layer, and the planarization layer 110 can be regarded as a second planarization layer. The padding portion 11 can be manufactured simultaneously by the process of the first planarization layer.

It should be noted that FIG. 4 only illustrates the film layer structure of the display panel provided by one of the embodiments, and does not represent the film layer structure of the display panel in practical applications. In some other embodiments, the display panel may also have only one source and drain layer, the source and drain layer may be disposed above the organic material layer, and the organic material layer may be regarded as a planarization layer of the display panel.

In some embodiments, as shown in FIG. 2 and FIG. 4, the light-emitting common layer 2 includes an organic common layer 21 and a cathode layer 22 disposed on the organic common layer 21. The organic common layer 21 may include, but is not limited to, a hole injection layer, a hole transport layer, an electron transport layer, and an electron injection layer. The display panel further includes an organic light-emitting material layer, and the organic light-emitting material layer is disposed between the hole transport layer and the electron transport layer and located in pixel openings defined by a pixel definition layer.

In some embodiments, the thickness of the padding portion 11 is less than the thickness of a part of the organic material layer 108 located in the display area AA.

As shown in FIG. 3 and FIG. 4, the padding portion 11 has a second thickness h2, the part of the organic material layer 108 located in the display area AA has a third thickness h3, and the second thickness h2 is less than the third thickness h3. It should be noted that if the thickness of the padding portion 11 is too small, the light-emitting common layer 2 may fill the first undercut opening UC1 defined between the first lateral surface 11a of the padding portion 11 and the partition portion 12, and continuously form a film on the first lateral surface 11a of the padding portion 11 and the third lateral surface 12a of the partition portion 12, so that the light-emitting common layer 2 cannot be interrupted at the first undercut opening UC1; if the thickness of the padding portion 11 is too large, it is not conducive to the continuous film formation of the encapsulation layer 114 at the second undercut opening UC2, which increases the risk of cracks in the encapsulation layer 114 and affects the encapsulation performance of the display panel.

In the embodiments, the thickness of the padding portion 11 is reduced, so that the thickness of the padding portion 11 is less than the thickness of the organic material layer 108, which can not only ensure that the light-emitting common layer 2 is interrupted at the first undercut opening UC1, but also facilitate the continuous film formation of the encapsulation layer 114 at the second undercut opening UC2, thereby improving the encapsulation performance of the display panel and improving the reliability of the display panel.

In some embodiments, a ratio of the thickness of the padding portion 11 to the thickness of the part of the organic material layer 108 located in the display area AA is greater than or equal to 3:25 and is less than or equal to 2:3. For example, the ratio of the second thickness h2 to the third thickness h3 may be 3:25, 1:5, 2:5, 1:2, or 2:3, etc.

In some embodiments, the thickness of the padding portion 11 is greater than or equal to 0.3 microns and is less than or equal to 1 micron, for example, the thickness of the padding portion 11 may be 0.3 microns, 0.5 microns, 0.7 microns, 0.9 microns, or 1 micron, etc.

In some embodiments, the thickness of the organic material layer 108 is greater than or equal to 1.5 microns and is less than or equal to 2.5 microns. For example, the thickness of the organic material layer 108 may be 1.5 microns, 1.7 microns, 1.9 microns, 2 microns, 2.2 microns, 2.4 microns, or 2.5 microns, etc.

In some embodiments, as shown in FIG. 3, there is a first included angle a1 between a reference plane and a tangent line of any point on the inwardly contracted lateral surface of the padding portion 11, the first included angle a 1 is greater than or equal to 50 degrees and is less than or equal to 80 degrees, and the reference plane is parallel to a light-emitting surface of the display panel. For example, the first included angle a 1 may be 50 degrees, 55 degrees, 60 degrees, 65 degrees, 70 degrees, 75 degrees, or 80 degrees, etc. In this way, it can not only ensure that the light-emitting common layer 2 is interrupted at the first undercut opening UC1, but also facilitate the continuous film formation of the encapsulation layer 114 at the first undercut opening UC1, so as to improve the encapsulation performance of the display panel and improve the reliability of the display panel.

In some embodiments, as shown in FIG. 2 and FIG. 3, the second lateral surface 11b of the padding portion 11 extends outwardly relative to the fourth lateral surface 12b of the partition portion 12, and the fourth lateral surface 12b of the partition portion 12 is a continuously arranged vertical lateral surface or an inclined lateral surface, that is, neither the second lateral surface 11b of the padding portion 11 nor the fourth lateral surface 12b of the partition portion 12 is provided with an undercut opening.

In some embodiments, as shown in FIG. 4, the encapsulation layer 114 includes a first inorganic encapsulation layer 1141, an organic encapsulation layer 1142, and a second inorganic encapsulation layer 1143 stacked in sequence.

In some embodiments, as shown in FIG. 2 and FIG. 3, the first retaining wall 1 further includes a blocking portion 13, the blocking portion 13 is stacked on the partition portion 12, and the thickness of the blocking portion 13 is greater than the thickness of the padding portion 11 and the thickness of the partition portion 12. By providing the blocking portion 13 with a larger thickness on the partition portion 12, the blocking portion 13 is configured to block an organic encapsulation material in the encapsulation layer 114 from overflowing, thereby further improving the encapsulation effect of the display panel.

In some embodiments, one lateral surface of the partition portion 12 is provided with the second undercut opening UC2, and a part of the blocking portion 13 is disposed on the padding portion 11 and covers another lateral surface of the partition portion 12. The blocking portion 13 is configured to cover the another lateral surface of the partition portion 12, so that the partition portion 12 can be insulated and separated from the light-emitting common layer 2 to prevent the partition portion 12 from overlapping the light-emitting common layer 2, thereby preventing electrochemical corrosion of the light-emitting common layer 2 in the non-display area NA.

As shown in FIG. 3, the third lateral surface 12a of the partition portion 12 is provided with the second undercut opening UC2, the second lateral surface 11b of the padding portion 11 extends beyond the fourth lateral surface 12b of the partition portion 12, and a part of the blocking portion 13 is disposed on the part of the padding portion 11 extending beyond the partition portion 12 and covers the fourth lateral surface 12b of the partition portion 12, so that the partition portion 12 can be insulated and separated from the light-emitting common layer 2, so as to avoid overlapping between the partition portion 12 and the light-emitting common layer 2, thereby preventing electrochemical corrosion of the light-emitting common layer 2 in the non-display area NA.

In some embodiments, as shown in FIG. 3 and FIG. 4, the blocking portion 13 includes a first blocking sub-portion 131, a second blocking sub-portion 132, and a third blocking sub-portion 133 stacked in sequence. The first blocking sub-portion 131 and the planarization layer 110 are disposed in the same layer and made of the same material; the second blocking sub-portion 132 and the pixel definition layer 112 are disposed in the same layer and made of the same material; and the third blocking sub-portion 133 and the supporting layer 113 are disposed in the same layer and made of the same material.

In some embodiments, as shown in FIG. 2, the display panel further includes a second retaining wall 4. The second retaining wall 4 is disposed on a side of the first retaining wall 1 away from the display area AA, the second retaining wall 4 extends along the edge of the display area AA, and the second retaining wall 4 may be configured to prevent the organic encapsulation material in the encapsulation layer 114 from overflowing.

In some embodiments, a vertical distance between a top of the first retaining wall 1 and the substrate 10 is greater than a vertical distance between a top of the second retaining wall 4 and the substrate 10.

As shown in FIG. 2, the vertical distance between the top of the first retaining wall 1 and the substrate 10 is defined as a fifth distance d5, and the fifth distance d5 refers to the height of the first retaining wall 1 itself; the vertical distance between the top of the second retaining wall 4 and the substrate 10 is defined as a sixth distance d6, and the sixth distance d6 refers to the height of the second retaining wall 4 itself. By adding the padding portion 11 and the partition portion 12 in the first retaining wall 1, it can not only ensure that the light-emitting common layer 2 is interrupted at the first retaining wall 1, but also make the height of the first retaining wall 1 greater than the height of the second retaining wall 4, so that the organic encapsulation material in the encapsulation layer 114 can be limited to the side of the first retaining wall 1 close to the display area AA to prevent the organic encapsulation material from overflowing, thereby further improving the encapsulation effect of the display panel.

In some embodiments, as shown in FIG. 2 and FIG. 3, the display panel includes a plurality of partition members 3. At least one partition member 3 is disposed on a side of the first retaining wall 1 close to the display area AA, and multiple partition members 3 are disposed on a side of the first retaining wall 1 away from the display area AA and located between the first retaining wall 1 and the second retaining wall 4. A lateral surface of the partition member 3 close to the display area AA and a lateral surface of the partition member 3 away from the display area AA are both provided with a third undercut opening UC3, and the light-emitting common layer 2 is interrupted at the third undercut openings UC3 of the partition member 3, so that the light-emitting common layer 2 in the non-display area NA can be divided into a plurality of mutually interrupted parts, which can not only prevent an electrical signal of the light-emitting common layer 2 in the display area AA from being transmitted to the light-emitting common layer 2 in the non-display area NA, avoid electrochemical corrosion between the light-emitting common layer 2 in the non-display area NA and an adjacent metal film layer, but also cut off a path of water vapor in an external environment entering the display area AA through the light-emitting common layer 2 in the non-display area NA, thereby further improving a encapsulation effect of the display panel.

In some embodiments, as shown in FIG. 3, the partition member 3 includes a fourth partition sub-portion 31, a fifth partition sub-portion 32, and a sixth partition sub-portion 33 stacked in sequence, and a lateral surface of the fifth partition sub-portion 32 contracts inwardly relative to the fourth partition sub-portion 31 and the partition sub-portion 33 to define a third undercut opening UC3.

In some embodiments, the partition portion 12, the partition members 3, and the second source and drain layer 109 are disposed in the same layer and made of the same material, and the partition portion 12, the partition members 3, and the second source and drain layer 109 may be manufactured simultaneously by using the same process, so that the light-emitting common layer 2 may be ensured to be interrupted at the first retaining wall 1 and the partition members 3 without increasing the film structure and process of the display panel, thereby improving the encapsulation performance of the display panel, avoiding poor display, and improving the reliability of the display panel.

In some embodiments, the second source and drain layer 109 is a three-layer metal thin film structure formed by sequentially stacking at least two metal materials, and the metal materials may include, but are not limited to, metal materials with good conductivity such as titanium, aluminum, copper, molybdenum, nickel, etc. For example, the second source and drain layer 109 is a three-layer metal thin film structure formed by sequentially stacking titanium, aluminum, and titanium.

In some embodiments, as shown in FIG. 3, the distance between the top of the partition portion 12 and the substrate 10 is greater than the distance between the top of the partition member 3 and the substrate 10.

In some embodiments, the first retaining wall 1 may be disposed in the second non-display area NA2. Specifically, the substrate 10 in the second non-display area NA2 is provided with the first retaining wall 1, the second retaining wall 4, and a plurality of partition members 3 arranged thereon. The second retaining wall 4 is located on a side of the first retaining wall 1 away from the display area AA, at least one partition member 3 is located on a side of the first retaining wall 1 close to the display area AA, and the plurality of partition members 3 are located between the first retaining wall 1 and the second retaining wall 4. In this way, the light-emitting common layer 2 in the second non-display area NA2 can be interrupted at the first undercut opening UC1 and the second undercut opening UC2 of the first retaining wall 1, thereby improving the encapsulation effect at the second non-display area NA2.

In some embodiments, the first non-display area NA1 and the second non-display area NA2 may be provided with the first retaining wall 1 at the same time, which can improve the encapsulation effect of the display panel in the first non-display area NA1 and the second non-display area NA2.

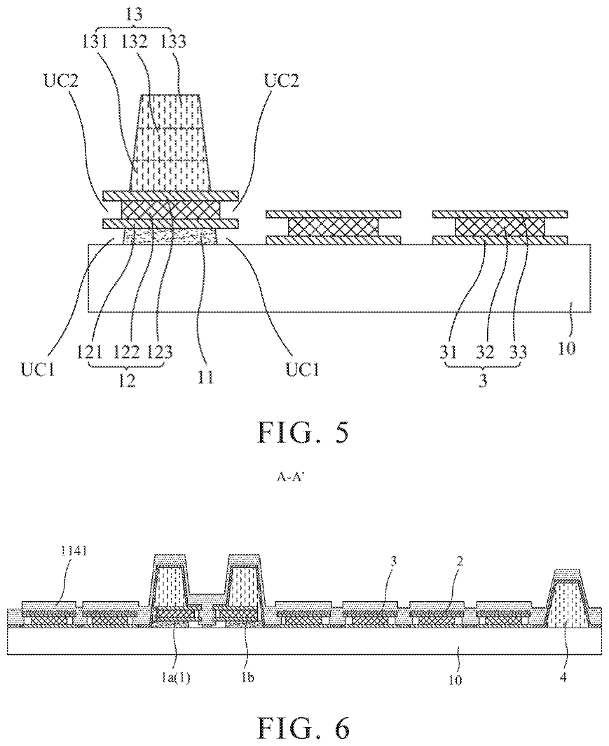

As shown in FIG. 5, FIG. 5 is a schematic structural diagram of another first retaining wall in the display panel provided by embodiments of the present disclosure, and the structure of the another first retaining wall is substantially the same as the structure of the first retaining wall in the display panel shown in FIG. 3, except that: the second lateral surface 11b of the padding portion 11 contracts inwardly relative to the fourth lateral surface 12b of the partition portion 12 to form a first undercut opening UC1, and the fourth lateral surface 12b of the partition portion 12 is provided with a second undercut opening UC2. That is, the lateral surface of the padding portion 11 close to the display area AA and the lateral surface of the padding portion 11 away from the display area AA are both defined with the partition portion 12 to form the first undercut opening UC1, and the lateral surface of the partition portion 12 close to the display area AA and the lateral surface of the partition portion 12 away from the display area AA are both formed with the second undercut opening UC2, so that it can be ensured that the light-emitting common layer 2 is interrupted at the lateral surface of the first retaining wall 1 close to the display area AA at and the lateral surface of the first retaining wall 1 away from the display area AA, thereby further improving the encapsulation performance, avoiding the occurrence of poor display, and further improving the reliability of the display panel.

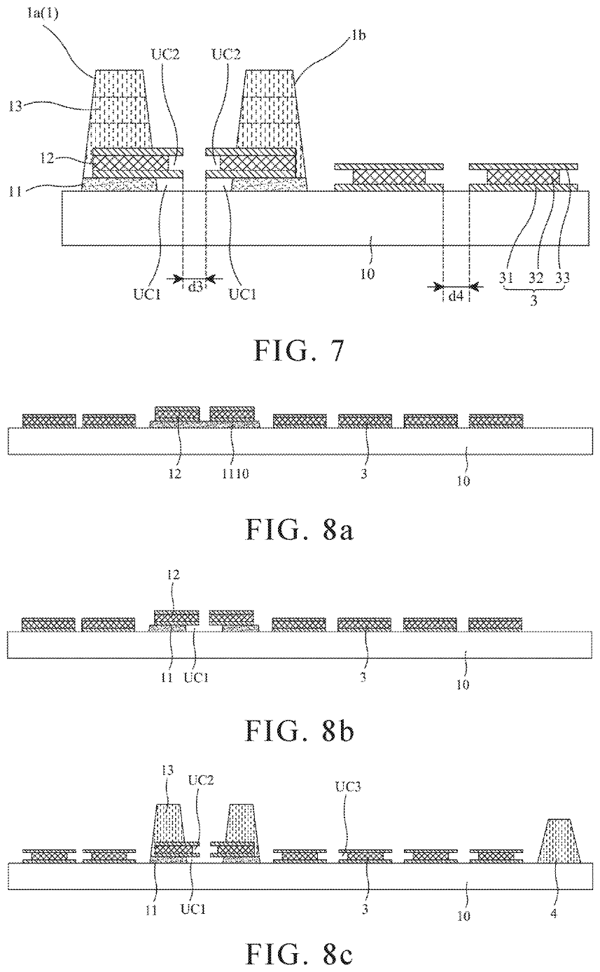

As shown in FIG. 6 and FIG. 7, FIG. 6 is a cross-sectional view of another display panel provided in embodiments of the present disclosure along the A-A′ direction shown in FIG. 1, and FIG. 7 is a schematic structural diagram of the first retaining wall in another display panel provided in embodiments of the present disclosure, and the structure of the another display panel is substantially the same as the structure of the display panel shown in FIG. 2 to FIG. 4, except that: the display panel includes two first retaining walls 1, the two first retaining walls 1 are a first sub-retaining wall 1a and a second sub-retaining wall 1b respectively, the first sub-retaining wall 1a and the second sub-retaining wall 1b are adjacent to and spaced apart from each other, the second sub-retaining wall 1b is located on a side of the first sub-retaining wall 1a away from the display area AA, and the first sub-retaining wall 1a and the second sub-retaining wall 1b are both arranged along the edge of the display area.

In the first sub-retaining wall 1a, at least one lateral surface of the padding portion 11 contracts inwardly relative to at least one lateral surface of the partition portion 12 on the same side, the at least one lateral surface of the partition portion 12 is provided with a second undercut opening UC2, and the light-emitting common layer 2 is interrupted at the second undercut opening UC2. In the second sub-retaining wall 1b, at least one lateral surface of the padding portion 11 contracts inwardly relative to at least one lateral surface of the partition portion 12 on the same side, the at least one lateral surface of the partition portion 12 is provided with a second undercut opening UC2, and the light-emitting common layer 2 is interrupted at the second undercut opening UC2. By arranging two first retaining walls 1 in the non-display area NA and arranging the two first retaining walls 1 adjacent to and spaced apart from each other, not only the organic encapsulation material in the encapsulation layer 114 can be blocked by the two first retaining walls 1 to further reduce the risk of overflow of the organic encapsulation material, but also the light-emitting common layer 2 can be partitioned into more interrupted parts to prevent electrochemical corrosion between the light-emitting common layer 2 in the non-display area NA and the overlapped metal film layer, and cut off the path of water vapor in the external environment entering the display area AA through the light-emitting common layer 2 in the non-display area NA, thereby further improving the encapsulation effect of the display panel.

In some embodiments, as shown in FIG. 6 and FIG. 7, the lateral surface of the padding portion 11 of the first sub-retaining wall 1a close to the second sub-retaining wall 1b is provided with a first undercut opening UC1, the lateral surface of the padding portion 11 of the second sub-retaining wall 1b close to the first sub-retaining wall 1a is provided with a first undercut opening UC1, the first undercut opening UC1 of the padding portion 11 of the first sub-retaining wall 1a and the first undercut opening UC1 of the padding portion 11 of the second sub-retaining wall 1b are arranged facing each other, so that the light-emitting common layer 2 between the first sub-retaining wall 1a and the second sub-retaining wall 1b is interrupted at the first undercut opening UC1 of the first sub-retaining wall 1a and the first undercut opening UC1 of the second sub-retaining wall 1b, a part of the light-emitting common layer 2 is formed on the substrate 10 between the first sub-retaining wall 1a and the second sub-retaining wall 1b, and the light-emitting common layer 2 between the first sub-retaining wall 1a and the second sub-retaining wall 1b is spaced apart and insulated from the partition portions 12 of the first sub-retaining wall 1a and the second sub-retaining wall 1b, so that the connection between the light-emitting common layer 2 in the non-display area NA and the light-emitting common layer in the display area AA can be cut off, the light-emitting common layer in the non-display area NA and other film layers are prevented from being electrochemically corroded, thereby improving the encapsulation effect of the display panel.

In the embodiments, the first inorganic encapsulation layer and the second inorganic encapsulation layer are continuously disposed at the first sub-retaining wall 1a and the second sub-retaining wall 1b to ensure the encapsulation effect of the display panel.

In some embodiments, as shown in FIG. 6, the display panel includes a plurality of partition members 3, at least one partition member 3 is disposed on a side of the first sub-retaining wall 1a close to the display area AA, the plurality of partition members 3 are disposed on a side of the second sub-retaining wall 1b away from the display area AA and located between the second sub-retaining wall 1b and the second retaining wall 4, and no partition member 3 is disposed between the first sub-retaining wall 1a and the second sub-retaining wall 1b.

In some embodiments, in a direction from the display area AA to the non-display area NA, a distance between the partition portion 12 of the first sub-retaining wall 1a and the partition portion 12 of the second sub-retaining wall 1b is equal to a distance between two adjacent partition members 3.

As shown in FIG. 6 and FIG. 7, in the direction from the display area AA to the non-display area NA, there is a third distance d3 between the partition portion 12 of the first sub-retaining wall 1a and the partition portion 12 of the second sub-retaining wall 1b, and there is a fourth distance d4 between two adjacent partition members 3, and the third distance d3 is equal to the fourth distance d4. It should be noted that if the distance between the partition portion 12 of the first sub-retaining wall 1a and the partition portion 12 of the second sub-retaining wall 1b is too large, the width of the non-display area NA may be increased, resulting in a decrease in the screen-to-body ratio; and if the distance between the partition portion 12 of the first sub-retaining wall 1a and the partition portion 12 of the second sub-retaining wall 1b is too small, the light-emitting common layer 2 cannot be interrupted at the first sub-retaining wall 1a and the second sub-retaining wall 1b. By making the distance between the partition portion 12 of the first sub-retaining wall 1a and the partition portion 12 of the second sub-retaining wall 1b equal to the distance between two adjacent partition members 3, it can be ensured that the light-emitting common layer 2 is interrupted at the first sub-retaining wall 1a and the second sub-retaining wall 1b without affecting the screen-to-body ratio, thereby improving the encapsulation effect of the display panel.

In practical applications, the third distance d3 and the fourth distance d4 may also be unequal, and it is only necessary to ensure that the difference between the third distance d3 and the fourth distance d4 is within the process error range, so that the requirement on the process accuracy can be reduced.

In some embodiments, the vertical distance between the top of the first sub-retaining wall 1a and the substrate 10 is equal to the vertical distance between the top of the second sub-retaining wall 1b and the substrate 10, that is, the height of the first sub-retaining wall 1a is equal to the height of the second sub-retaining wall 1b.

With reference to FIG. 8a to FIG. 8c, FIG. 8a to FIG. 8c are schematic flowcharts of a method for manufacturing the display panel provided in embodiments of the present disclosure. Taking the display panel shown in FIG. 6 as an example, the method for manufacturing the display panel includes the following steps:
Step S1, as shown in FIG. 8a, forming a layer of organic material on a substrate 10, and patterning the organic material to form an organic material layer (not shown) and a padding layer 1110;
Step S2, as shown in FIG. 8a, depositing a conductive material on the organic material layer, and patterning the conductive material to form a partition portion 12 located on the padding layer and a plurality of partition members 3 located on the substrate 10;
Step S3, as shown in FIG. 8b, patterning the padding layer by an ashing process to remove part of the padding layer and form a padding portion 11, where a lateral surface of the padding portion 11 contracts inwardly relative to a lateral surface of the partition portion 12 to form a first undercut opening UC1;
Step S4, as shown in FIG. 8c, forming a blocking portion 13 on the partition portion 12 to form a first retaining wall 1, and forming a second retaining wall 4 on the substrate 10 on a side of the first retaining wall 1 away from the display area AA; and performing side etching processing on the partition portion 12 and the partition members 3, forming a second undercut opening UC2 on a lateral surface of the partition portion 12, and forming a third undercut opening UC3 on a lateral surface of the partition member 3; and
Step S5, sequentially forming a light-emitting common layer and an encapsulation layer (not shown in the figures) on the substrate 10 and the blocking portion 13, the light-emitting common layer is interrupted at the first undercut opening UC1, the second undercut opening UC2, and the third undercut opening UC3, and the encapsulation layer is continuously formed into a film at the first undercut opening UC1, the second undercut opening UC2, and the third undercut opening UC3.

It should be noted that FIG. 8a to FIG. 8c mainly illustrate the manufacturing process of the first retaining wall 1, and do not illustrate the complete manufacturing process of the display panel, and before step S1, film layers such as an active layer, a first gate insulating layer, a first gate layer, a second gate insulating layer, a second gate layer, an interlayer dielectric layer, and a first source and drain layer should also be formed on the substrate, the above film layers are not illustrated in FIG. 8a to FIG. 8c, and the manufacturing process of the above film layers may refer to the existing display panel, which will not be repeated here.

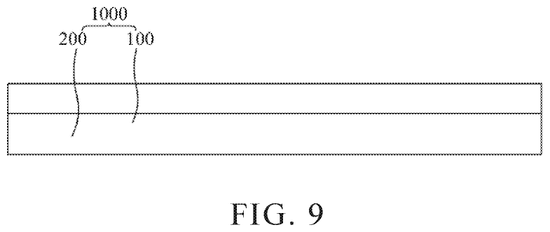

According to the display panel provided in the embodiments of the present disclosure, the embodiments of the present disclosure further provide a display device. As shown in FIG. 9, FIG. 9 is a schematic structural diagram of the display device provided in embodiments of the present disclosure, the display device 1000 includes a display panel 100 and a housing 200. The display panel 100 is disposed on the housing 200, and the display panel 100 may be the display panel provided by any one of the above embodiments, so as to achieve the same or similar functions in the display device provided in the embodiments of the present disclosure.

Beneficial effects of the embodiments of the present disclosure are as follows: the present disclosure provides a display panel and a display device. The display panel includes a first retaining wall and at least one light-emitting common layer. The first retaining wall is located in a non-display area and extends along an edge of a display area. The light-emitting common layer is partially disposed on the first retaining wall. The first retaining wall includes a padding portion and a partition portion stacked on the padding portion. At least one lateral surface of the padding portion of the first retaining wall contracts inwardly relative to at least one lateral surface of the partition portion on the same side to form a first undercut opening, so that the light-emitting common layer can be prevented from continuously forming a film on the lateral surface of the first retaining wall, so as to ensure that the light-emitting common layer is interrupted at the first undercut opening. In this way, the light-emitting common layer in the non-display area is prevented from electrochemical corrosion, thereby improving the encapsulation performance of the display panel, avoiding poor display, and improving the reliability of the display panel.

In the description of the present disclosure, the terms “first” and “second” are only used for descriptive purposes, and cannot be understood as indicating or implying relative importance or implicitly indicating the number of indicated technical features. Therefore, features defined with “first” and “second” may explicitly or implicitly include one or more features. In the description of the present disclosure, “plurality of” means two or more, unless otherwise specifically defined.

In the above embodiments, the description of each embodiment has its own emphasis, and for parts not described in detail in a certain embodiment, reference may be made to the relevant description of other embodiments.

Embodiments, implementations, and related technical features of the present disclosure may be combined and replaced with each other without conflict.

The above are only preferred embodiments of the present disclosure and do not limit the present disclosure in any form. Any simple modifications, equivalent changes and modifications made to the above embodiments according to the technical essence of the present disclosure without departing from the content of the technical solutions of the present disclosure still fall within the scope of the technical solutions of the present disclosure.

What is claimed is:

1. A display panel, comprising a display area and a non-display area, wherein the display panel comprises:
a first retaining wall located in the non-display area and extending along an edge of the display area; and
at least one light-emitting common layer partially disposed on the first retaining wall;
wherein the first retaining wall comprises a padding portion and a partition portion stacked on the padding portion, at least one lateral surface of the padding portion contracts inwardly relative to at least one lateral surface of the partition portion on a same side to form a first undercut opening, and the light-emitting common layer is interrupted at the first undercut opening.

2. The display panel according to claim 1, wherein a distance by which a bottom of the at least one lateral surface of the padding portion contracts inwardly relative to a bottom of the at least one lateral surface of the partition portion on the same side is greater than a thickness of the light-emitting common layer.

3. The display panel according to claim 1, wherein the partition portion and the light-emitting common layer adjacent to the partition portion are spaced apart and insulated from each other.

4. The display panel according to claim 1, wherein a thickness of the padding portion is greater than a thickness of the light-emitting common layer.

5. The display panel according to claim 1, wherein the display panel comprises an organic material layer, and the padding portion and the organic material layer are disposed in a same layer and made of a same material.

6. The display panel according to claim 5, wherein a thickness of the padding portion is less than a thickness of a part of the organic material layer located in the display area.

7. The display panel according to claim 6, wherein a ratio of the thickness of the padding portion to the thickness of the part of the organic material layer located in the display area is greater than or equal to 3:25 and is less than or equal to 2:3.

8. The display panel according to claim 5, wherein the display panel comprises at least one source and drain layer, and the at least one source and drain layer is disposed on the organic material layer.

9. The display panel according to claim 1, wherein an included angle between a reference plane and a tangent line of any point on the at least one lateral surface of the padding portion is greater than or equal to 50 degrees and is less than or equal to 80 degrees, and the reference plane is parallel to a light-emitting surface of the display panel.

10. The display panel according to claim 1, wherein the first retaining wall further comprises a blocking portion, the blocking portion is stacked on the partition portion, and a thickness of the blocking portion is greater than a thickness of the padding portion and a thickness of the partition portion.

11. The display panel according to claim 10, wherein one lateral surface of the partition portion is provided with the first undercut opening, and a part of the blocking portion is disposed on the padding portion and covers another lateral surface of the partition portion.

12. The display panel according to claim 1, wherein the display panel comprises two first retaining walls, the two first retaining walls comprise a first sub-retaining wall and a second sub-retaining wall adjacent to and spaced apart from each other, and the second sub-retaining wall is located on a side of the first sub-retaining wall away from the display area.

13. The display panel according to claim 12, wherein a lateral surface of the padding portion of the first sub-retaining wall close to the second sub-retaining wall is provided with the first undercut opening, and a lateral surface of the padding portion of the second sub-retaining wall close to the first sub-retaining wall is provided with the first undercut opening.

14. The display panel according to claim 13, wherein the display panel comprises a plurality of partition members, the light-emitting common layer is interrupted at the partition members, at least one of the partition members is disposed on a side of the first sub-retaining wall close to the display area, and the plurality of partition members are disposed on a side of the second sub-retaining wall away from the display area; and
wherein in a direction parallel to a light-emitting surface of the display panel, a distance between the partition portion of the first sub-retaining wall and the partition portion of the second sub-retaining wall is equal to a distance between two adjacent ones of the partition members.

15. The display panel according to claim 1, wherein the display panel comprises a substrate and a second retaining wall, the first retaining wall and the second retaining wall are disposed on the substrate, and the second retaining wall is located on a side of the first retaining wall away from the display area; and
wherein a vertical distance between a top of the first retaining wall and the substrate is greater than a vertical distance between a top of the second retaining wall and the substrate.

16. The display panel according to claim 1, wherein the at least one lateral surface of the partition portion is provided with a second undercut opening, and the light-emitting common layer is interrupted at the second undercut opening.

17. The display panel according to claim 16, wherein a distance by which a bottom of the at least one lateral surface of the padding portion contracts inwardly relative to a bottom of the at least one lateral surface of the partition portion on the same side is greater than a depth of the second undercut opening.

18. The display panel according to claim 16, wherein the partition portion comprises a first partition sub-portion, a second partition sub-portion, and a third partition sub-portion stacked in sequence; and
wherein at least one lateral surface of the second partition sub-portion contracts inwardly relative to at least one lateral surface of the first partition sub-portion and at least one lateral surface of the third partition sub-portion on a same side to form the second undercut opening.

19. The display panel according to claim 1, wherein the display panel comprises a plurality of light-emitting common layers, and the plurality of light-emitting common layers comprise an organic common layer and a cathode layer disposed on the organic common layer.

20. A display device, comprising a display panel, the display panel comprising a display area and a non-display area, wherein the display panel comprises:
a first retaining wall located in the non-display area and extending along an edge of the display area; and
at least one light-emitting common layer partially disposed on the first retaining wall;
wherein the first retaining wall comprises a padding portion and a partition portion stacked on the padding portion, at least one lateral surface of the padding portion contracts inwardly relative to at least one lateral surface of the partition portion on a same side to form a first undercut opening, and the light-emitting common layer is interrupted at the first undercut opening.
